(19) United States
(12) Patent Application Publication
(10) Pub. No.: US 2012/0146738 A1
(43) Pub. Date: Jun. 14, 2012

(54) PIEZOELECTRIC OSCILLATOR

(75) Inventor: Takashi MATSUMOTO, Sayama (JP)

(73) Assignee: Nihon Dempa Kogyo Co., Ltd., Tokyo (JP)

(21) Appl. No.: 13/309,846

(22) Filed: Dec. 2, 2011

(30) Foreign Application Priority Data
Dec. 10, 2010 (JP) P.2010-275388
Aug. 24, 2011 (JP) P.2011-182798

(51) Int. Cl. H03B 5/32

(52) U.S. Cl. 331/158

(57) ABSTRACT

Provided is a piezoelectric oscillator which can easily perform adjustment of oscillation frequency at a low cost and which can restrain frequency changes due to power supply voltage variations. The piezoelectric oscillator includes a frequency adjustment circuit and an oscillator circuit and is configured such that: a cathode of a variable-capacitance diode D3 is connected to an input side of the oscillator circuit; the cathode is further connected to a control voltage electrode of a potentiometer Rv via a third resistor R3; and a power supply voltage Vcc is applied to the potentiometer Rv via a regulator. Accordingly, even when the power supply voltage fluctuates, the piezoelectric oscillator can restrain frequency changes by applying a constant voltage to the cathode of the variable-capacitance diode D3, and adjusts frequency by changing a voltage to be applied from the potentiometer Rv to the cathode of the variable-capacitance diode D3.

This application has a priority of Japanese no. 2010-275388 filed Dec. 10, 2010, and no. 2011-182798 filed Aug. 24, 2011, hereby incorporated by reference.

### BACKGROUND OF THE INVENTION

1. Field of the Invention

The present invention relates to a piezoelectric oscillator, and more specifically, to a piezoelectric oscillator which easily performs adjustment of its oscillation frequency at a low cost and which can restrain frequency changes due to power supply voltage variations.

2. Description of the Related Art

### [Prior Art]

As a method for adjusting oscillation frequency of an oscillator, there is a method in which load capacitance is changed by replacing a fixed capacitor.

### [Conventional Piezoelectric Oscillator: FIG. 5]

A conventional piezoelectric oscillator is described with reference to FIG. 5. FIG. 5 is a circuit diagram of a conventional piezoelectric oscillator.

As shown in FIG. 5, the conventional piezoelectric oscillator is configured such that: an input signal is input into one end of a first resistor R1; another end of the first resistor R1 is connected to a cathode of a first diode D1 and a cathode of a second diode D2; an anode of the first diode D1 is grounded; an anode of the second diode D2 is connected to one ends of capacitors C1 and C2 which are connected in parallel; another ends of the capacitors C1 and C2 are connected to an oscillator circuit 1; and the second diode D2 is grounded via a second resistor R2.

### [Conventional Frequency Adjusting Method]

The piezoelectric oscillator of FIG. 5 is constituted by just a capacitor C1 without providing a capacitor C2, and an appropriate capacitor C2 is attached thereto in consideration of a target frequency of the oscillator, so that the load capacitance of the circuit is made large to adjust oscillation frequency.

### 2. Related Art

Note that, as a related conventional technique, there is Japanese Patent Application Laid-Open No. 2000-183650 “Piezoelectric Oscillator” (Toyo Communication Equipment Co., Ltd.) [Patent Document 1].

Patent Document 1 discloses that an originally setting frequency can be maintained even if lines or the like for controlling the frequency of a crystal oscillator are cut. It is shown that one end of a series connection circuit, which is constituted by a first resistor, a digital variable resistor IC, and a second resistor, is connected to a power supply of the crystal oscillator, and another end thereof is grounded; and an output voltage of the digital variable resistor IC is connected to a cathode of a variable-capacitance diode.
[Patent Document 1] Japanese Patent Application Laid-Open No. 2000-183650

### SUMMARY OF THE INVENTION

However, the conventional piezoelectric oscillator requires attaching and replacing operations of a capacitor chip of the capacitor C2 to adjust its frequency, and the adjustment operation is performed such that: the frequency is measured before the capacitor chip of the capacitor C2 is attached; solder application is performed to solder the capacitor chip; the frequency is measured again for check; and then the soldering is checked. Thus, the conventional piezoelectric oscillator has a problem that it requires such large man-hours.

Further, with the conventional piezoelectric oscillator, due to variation in capacitance ratio of the crystal resonator, the frequency does not fall in the standard only by one adjustment.

The piezoelectric oscillator according to Patent Document 1 performs fine adjustment of the frequency by the variable resistor IC, but does not have a function to restrain frequency changes due to power supply voltage variations.

### SUMMARY OF THE INVENTION

The present invention is accomplished in view of the above facts, and an object of the present invention is to provide a piezoelectric oscillator which can easily adjust oscillation frequency at a low cost and which can restrain frequency changes due to power supply voltage variations.

In order to solve the problems of the conventional example, the present invention is a piezoelectric oscillator including a frequency adjustment circuit and an oscillator circuit, which frequency adjustment circuit is configured such that: a cathode of a first diode is connected via a first resistor to an input terminal into which a control voltage is input and an anode of the first diode is grounded; a cathode of a second diode is connected to the input terminal via the first resistor, an anode of the second diode is connected to an anode of a variable-capacitance diode, and a cathode of the variable-capacitance diode is connected to the oscillator circuit; the anode of the second diode and the anode of the variable-capacitance diode are grounded via a second resistor; and the cathode of the variable-capacitance diode is connected to a control voltage electrode for outputting a control voltage of a potentiometer, one end of the potentiometer is connected to a power supply voltage via a regulator which keeps a voltage constant, and an another end of the potentiometer is grounded. The present invention has such effects that adjustment of the oscillation frequency can be easily performed at a low cost and that frequency changes due to power supply voltage variations can be restrained.

In the present invention, the piezoelectric oscillator is such that the cathode of the variable-capacitance diode and the control voltage electrode of the potentiometer are connected via a third resistor.

In the present invention, the piezoelectric oscillator is configured such that the another end of the potentiometer which is grounded is grounded via a thermistor. This yields such an effect that the temperature compensation can be performed in accordance with an ambient temperature, so that frequency stabilization can be performed at high accuracy.

In the present invention, the piezoelectric oscillator is configured such that a fourth resistor is connected in parallel to the thermistor.

In the present invention, the piezoelectric oscillator is configured such that when a value of an internal variable resistance is changed, the potentiometer controls a voltage to be applied to the variable-capacitance diode.

In the present invention, the piezoelectric oscillator is configured such that the potentiometer performs adjustment of frequency in such a manner that the potentiometer increases the frequency by increasing the voltage to be applied to the variable-capacitance diode so as to decrease capacitance, and decreases the frequency by decreasing the voltage to be applied so as to increase the capacitance. Accordingly, the present invention has an effect that the adjustment of the frequency can be easily performed at a low cost.

In the present invention, the piezoelectric oscillator is configured such that the potentiometer is a digital potentiometer having a memory, and the memory stores therein a value of the variable resistance.

### BRIEF DESCRIPTION OF THE DRAWINGS

FIG. 1 is a circuit diagram of a first piezoelectric oscillator according to an embodiment of the present invention.

FIG. 2 is a view showing a relation between applied voltage of a variable-capacitance diode D3 and frequency change.

FIG. 3 is a circuit diagram of a second piezoelectric oscillator according to an embodiment of the present invention.

FIG. 4 is a view showing a temperature-frequency characteristic.

FIG. 5 is a circuit diagram of a conventional piezoelectric oscillator.

### DESCRIPTION OF REFERENCE NUMERALS

1 . . . Oscillator circuit, 2 . . . Regulator (IC), R1 . . . First resistor, R2 . . . Second resistor, R3 . . . Third resistor, R4 . . . Fourth resistor, D1 . . . First diode, D2 . . . Second diode, D3 . . . Variable-capacitance diode, Rv . . . Potentiometer, C1, C2 . . . Capacitor, TH1 . . . Thermistor

### DESCRIPTION OF THE PREFERRED EMBODIMENT

Embodiments of the present invention are described with reference to drawings.

### Summary of Preferred Embodiment

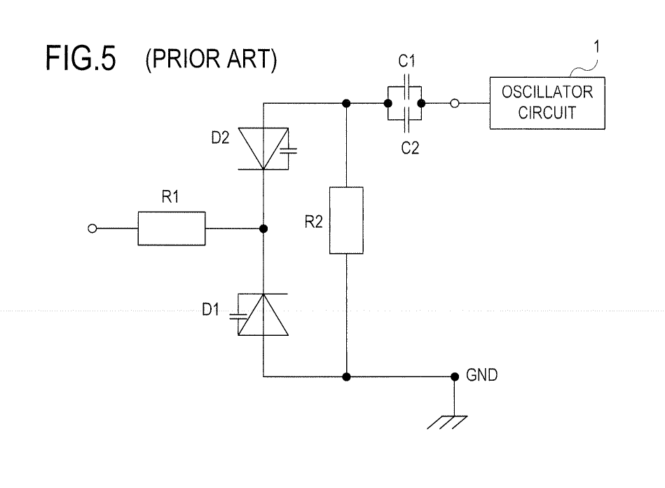

A piezoelectric oscillator according to an embodiment of the present invention is a piezoelectric oscillator in which: a variable-capacitance diode is provided instead of fixed capacitors (capacitors C1 and C2 connected in parallel (FIG. 5)) which are provided on an input side of an oscillator circuit; a cathode side of the variable-capacitance diode is connected to a potentiometer via a resistor; and further, a power supply voltage is connected to the potentiometer via a regulator. In this configuration, a given voltage which is divided by the variable-capacitance diode can be applied to the input side of the oscillator circuit, and further, a voltage to be applied to the potentiometer can be maintained constant by the regulator. As a result, even if any fluctuation in power supply voltage occurs, it is possible to prevent frequency changes.

Further, in the above configuration, the piezoelectric oscillator according to the embodiment of the present invention is further configured such that a terminal to be grounded of the potentiometer is grounded via a thermistor. This causes a voltage to be applied to the variable-capacitance diode to be changed in response to an ambient temperature and the capacitance of the variable-capacitance diode to be also changed in response to the ambient temperature, thereby causing temperature compensation of the circuit. As a result, it is possible to make frequency stability high accurate.

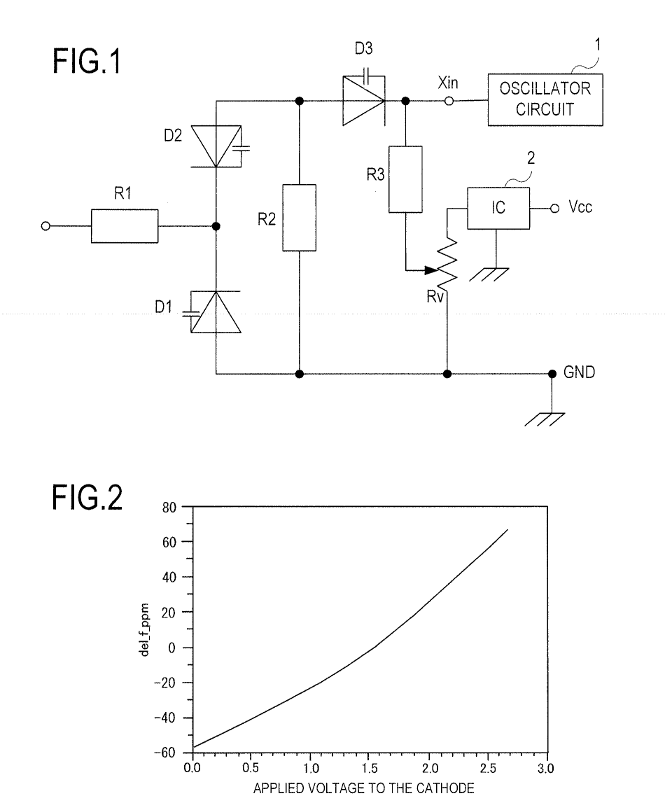

### [First Piezoelectric Oscillator: FIG. 1]

A first piezoelectric oscillator according to an embodiment of the present invention is described with reference to FIG. 1. FIG. 1 is a circuit diagram of the first piezoelectric oscillator according to the embodiment of the present invention.

As shown in FIG. 1, the first piezoelectric oscillator according to the embodiment of the present invention (the first piezoelectric oscillator) is configured such that: an input signal is input from an input terminal; the input terminal is connected to one end of a first resistor R1; another end of the first resistor R1 is connected to a cathode of a first diode D1 and a cathode of a second diode D2; an anode of the first diode D1 is grounded; an anode of the second diode D2 is connected to an anode of a variable-capacitance diode D3; a cathode of the variable-capacitance diode D3 is connected to an oscillator circuit 1; an anode of the second diode D2 and an anode of the variable-capacitance diode D3 are grounded via a second resistor R2; a cathode of the variable-capacitance diode D3 is connected to a control voltage electrode of a potentiometer Rv via a third resistor R3; a power supply voltage Vcc is connected to one end of the potentiometer via a regulator (IC) 2; and another end of the potentiometer Rv is grounded.

### [Each Member: FIG. 2]

Each characteristic member of the first piezoelectric oscillator will be explained concretely.

The variable-capacitance diode D3 is configured to adjust a voltage to be applied to the oscillator circuit 1 by causing capacitance changeable, so that oscillation frequency of the oscillator circuit 1 is changed to be adjusted.

A potential of 0 V is given to an anode side of the variable-capacitance diode D3 by the second resistor R2.

A voltage of a cathode side of the variable-capacitance diode D3 is controlled by the potentiometer Rv.

As the potentiometer Rv, a digital potentiometer is used. The potentiometer Rv includes: a power supply voltage terminal into which a power supply voltage is input; an earth terminal to be connected to a GND (ground); and a control voltage electrode which outputs a given controlled voltage.

Note that, the power supply voltage is not directly applied to the power supply voltage terminal, but is applied thereto via the regulator 2.

Inside the potentiometer Rv, values of a variable resistance are set, so that a voltage from the regulator 2 is divided so as to be applied to the cathode of the variable-capacitance diode D3 via the third resistor R3.

The regulator (IC: Integrated Circuit) 2 outputs a voltage which is continuously constant to a power supply voltage Vcc, to a power supply voltage terminal of the potentiometer Rv. For example, when the power supply voltage is 3.3 V, a constant voltage of 2.7 V is applied between the power supply voltage terminal of the potentiometer Rv and the GND.

Even if, due to this regulator 2, the power supply voltage fluctuates, the voltage to be applied to the power supply voltage terminal of the potentiometer Rv is constant and the divided voltage is also constant, so that a constant voltage is applied to the cathode of the variable-capacitance diode D3, thereby resulting in that the capacitance of the variable-capacitance diode D3 does not fluctuate.

Note that for a normal Colpitts oscillator circuit, when the power supply voltage fluctuates, the capacitance of a transistor for oscillation is changed and its frequency fluctuates by the change of an oscillation level.

The first piezoelectric oscillator can restrain frequency changes. In view of this, in comparison with a conventional voltage controlled crystal oscillator (VCXO: Voltage Controlled Crystal Oscillator), the first piezoelectric oscillator can improve the frequency changes due to the fluctuation in power supply voltage to about 1/10 to 1/100 of those of the conventional voltage controlled crystal oscillator.

### [Operation]

The operation of the frequency adjustment in the first piezoelectric oscillator is described below.

When the oscillation frequency is lower than a target frequency in the first piezoelectric oscillator, the potentiometer Rv controls a voltage to be applied to the cathode of the variable-capacitance diode D3 to be increased. This decreases a capacitance value of the variable-capacitance diode D3, thereby increasing a frequency oscillated from the oscillator circuit 1.

In the meantime, when the oscillation frequency is higher than the target frequency in the first piezoelectric oscillator, the potentiometer Rv controls the voltage to be applied to the cathode of the variable-capacitance diode D3 to be decreased. This increases the capacitance value of the variable-capacitance diode D3, thereby decreasing the frequency oscillated from the oscillator circuit 1.

Since the digital potentiometer used in the first piezoelectric oscillator includes two types of memories, i.e., volatile and nonvolatile memories, it can hold resistance values temporarily and semipermanently.

The resistance values stored in the memories are rewritable by an external control apparatus. Alternatively, a plurality of resistance values may be stored in the memories so that an external control apparatus may select a resistance value to use.

This makes it possible to perform re-adjustment of the frequency by use of resistance values in the memories.

### [Applied Voltage and Frequency Change: FIG. 2]

A relation between voltage to be applied to the cathode of the variable-capacitance diode D3 and frequency change is shown in FIG. 2. FIG. 2 is a view showing the relation between the applied voltage of the variable-capacitance diode D3 and the frequency change. Here, the transverse axis shows the voltage (V) to be applied, and the vertical axis shows frequency change amplitude (del_f_ppm).

As shown in FIG. 2, when the voltage to be applied to the cathode of the variable-capacitance diode D3 fluctuates, a change state of the frequency occurs.

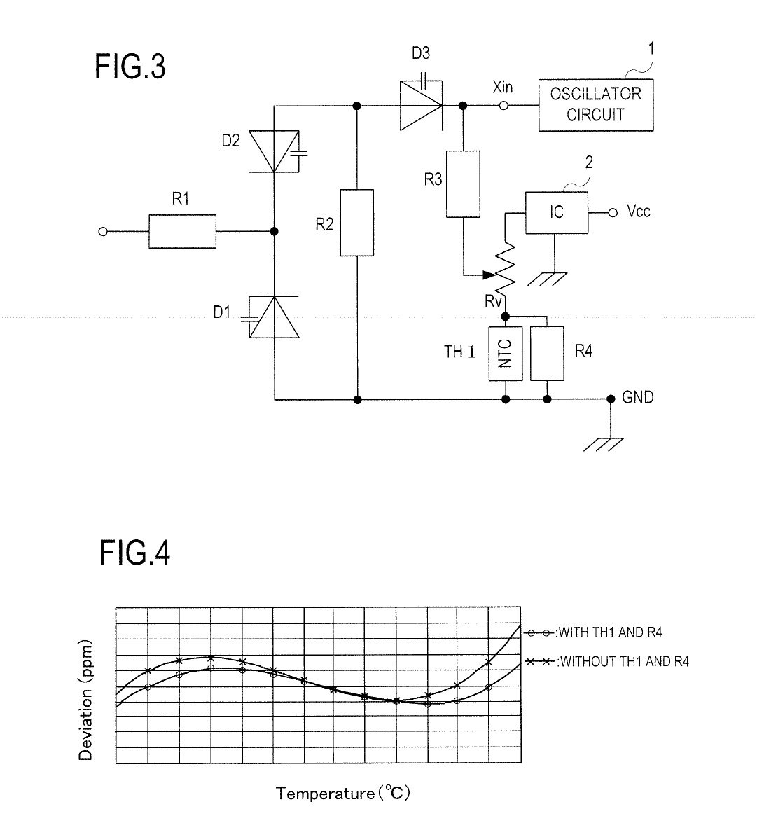

### [Second Piezoelectric Oscillator: FIG. 3]

Next will be explained a second piezoelectric oscillator according to an embodiment of the present invention (the second piezoelectric oscillator) with reference to FIG. 3. FIG. 3 is a circuit diagram of the second piezoelectric oscillator according to the embodiment of the present invention.

As shown in FIG. 3, the second piezoelectric oscillator is similar to the first piezoelectric oscillator, but different from the first piezoelectric oscillator in that the GND-side terminal of the potentiometer Rv is not directly connected to the GND, but is connected to the GND via a parallel connection circuit constituted by a thermistor (NTC: Negative Temperature Coefficient) TH1 and a resistor R4.

In other words, one end of the thermistor TH1 and one end of the resistor R4 are connected to the another end of potentiometer Rv, and another end of the thermistor TH1 and another end of the resistor R4 are grounded.

The variable-capacitance diode D3 is an element used for frequency adjustment, and will also serve as an element which performs temperature compensation, when the configuration of the thermistor TH1 and the resistor R4 is added thereto.

The thermistor TH1 is configured to change a resistance value when an ambient temperature of this circuit changes, thereby changing the voltage to be applied to the variable-capacitance diode D3 along with the ambient temperature.

Further, the resistor R4 connected thereto in parallel has a function to make the curve of the temperature-frequency characteristic moderate.

The second piezoelectric oscillator has a mechanism in which the capacitance of the variable-capacitance diode D3 changes along with the ambient temperature, thereby changing output frequency of the oscillator circuit 1. Thus, the second piezoelectric oscillator yields an effect to obtain an excellent temperature-frequency characteristic.

### [Temperature-frequency Characteristic: FIG. 4]

An oscillator generates heat by current flowing to a buffer circuit of ECL (Emitter Coupled Logic) output (including PECL [Positive ECL]), which is in high demand in recent years, and that has prevented the stability of the oscillator from being highly accurate.

The temperature-frequency characteristics of the first piezoelectric oscillator and the second piezoelectric oscillator in comparison with each other are described with reference to FIG. 4. FIG. 4 is a view showing the temperature-frequency characteristics. In FIG. 4, the vertical axis shows frequency deviation (Deviation [ppm]), and the transverse axis shows temperature (Temperature [° C.]). The frequency deviation is an acceptable deviation from a standard value of a frequency corresponding to a temperature.

The characteristic of the second piezoelectric oscillator is shown by a curve (with TH1 and R4) obtained by connecting small circles, and the characteristic of the first piezoelectric oscillator is shown by a curve (without TH1 and R4) obtained by connecting small x.

The second piezoelectric oscillator has a curve of which the deviation of the frequency to the temperature is moderate in comparison with the first piezoelectric oscillator.

In other words, with the use of the second piezoelectric oscillator, it is possible to cause the frequency change of the crystal resonator caused due to heat generation of a circuit to be temperature-compensated by capacitance control in a circuit side. Accordingly, by providing an automatic adjusting function of frequency together, it is possible to realize highly accurate frequency stability.

### Effects of Embodiments

The first piezoelectric oscillator includes a frequency adjustment circuit and an oscillator circuit 1, and is configured such that: a cathode of a variable-capacitance diode D3 is connected to an input side of the oscillator circuit 1; the cathode is further connected to a control voltage electrode of a potentiometer Rv via a third resistor R3; and a power supply voltage Vcc is applied to the potentiometer Rv via a regulator 2. This yields such effects that even for the fluctuation in power supply voltage, by applying a constant voltage to the cathode of the variable-capacitance diode D3, it is possible to restrain frequency changes, and that the adjustment of the frequency can be easily performed at a low cost by changing a voltage to be applied from the potentiometer Rv to the cathode of the variable-capacitance diode D3.

The second piezoelectric oscillator has a configuration in which a GND-side terminal of the potentiometer Rv is grounded via a parallel connection of a thermistor TH1 and a resistor R4, in addition to the configuration of the first piezoelectric oscillator. Accordingly, the voltage to be applied to the variable-capacitance diode D3 is changed in response to an ambient temperature, and therefore the capacitance of the variable-capacitance diode D3 is also changed in response to the ambient temperature, thereby allowing temperature compensation of the circuit. Thus, the second piezoelectric oscillator yields such an effect that frequency stability can be highly accurate.

The first and second piezoelectric oscillators have such an effect that frequency adjustment can be easily performed by a low-cost system with a combination of a PC (a computer) and a frequency counter.

Further, the adjustment tact is reduced to about 1/10 in comparison with the conventional adjusting method, and thus, a large cost improvement can be expected.

The present invention is preferably applicable to a piezoelectric oscillator which can easily perform adjustment of oscillation frequency at a low cost and which can restrain frequency changes due to power supply voltage variations.

1. A piezoelectric oscillator comprising a frequency adjustment circuit and an oscillator circuit, wherein:
the frequency adjustment circuit is configured such that:
a cathode of a first diode is connected via a first resistor to an input terminal into which a control voltage is input and an anode of the first diode is grounded;
a cathode of a second diode is connected to the input terminal via the first resistor, an anode of the second diode is connected to an anode of a variable-capacitance diode, and a cathode of the variable-capacitance diode is connected to the oscillator circuit;
the anode of the second diode and the anode of the variable-capacitance diode are grounded via a second resistor; and
the cathode of the variable-capacitance diode is connected to a control voltage electrode for outputting a control voltage of a potentiometer, one end of the potentiometer is connected to a power supply voltage via a regulator which keeps a voltage constant, and an another end of the potentiometer is grounded.

2. The piezoelectric oscillator according to claim 1, wherein the cathode of the variable-capacitance diode and the control voltage electrode of the potentiometer are connected via a third resistor.

3. The piezoelectric oscillator according to claim 1, wherein the another end of the potentiometer is grounded via a thermistor.

4. The piezoelectric oscillator according to claim 3, wherein a fourth resistor is connected in parallel to the thermistor.

5. The piezoelectric oscillator according to claim 1, wherein the potentiometer controls a voltage to be applied to the variable-capacitance diode, when a value of an internal variable resistance is changed.

6. The piezoelectric oscillator according to claim 2, wherein the potentiometer controls a voltage to be applied to the variable-capacitance diode, when a value of an internal variable resistance is changed.

7. The piezoelectric oscillator according to claim 3, wherein the potentiometer controls a voltage to be applied to the variable-capacitance diode, when a value of an internal variable resistance is changed.

8. The piezoelectric oscillator according to claim 4, wherein the potentiometer controls a voltage to be applied to the variable-capacitance diode, when a value of an internal variable resistance is changed.

9. The piezoelectric oscillator according to claim 5, wherein the potentiometer performs adjustment of frequency in such a manner that the potentiometer increases the frequency by increasing the voltage to be applied to the variable-capacitance diode so as to decrease capacitance, and decreases the frequency by decreasing the voltage to be applied so as to increase the capacitance.

10. The piezoelectric oscillator according to claim 6, wherein the potentiometer performs adjustment of frequency in such a manner that the potentiometer increases the frequency by increasing the voltage to be applied to the variable-capacitance diode so as to decrease capacitance, and decreases the frequency by decreasing the voltage to be applied so as to increase the capacitance.

11. The piezoelectric oscillator according to claim 7, wherein the potentiometer performs adjustment of frequency in such a manner that the potentiometer increases the frequency by increasing the voltage to be applied to the variable-capacitance diode so as to decrease capacitance, and decreases the frequency by decreasing the voltage to be applied so as to increase the capacitance.

12. The piezoelectric oscillator according to claim 8, wherein the potentiometer performs adjustment of frequency in such a manner that the potentiometer increases the frequency by increasing the voltage to be applied to the variable-capacitance diode so as to decrease capacitance, and decreases the frequency by decreasing the voltage to be applied so as to increase the capacitance.

13. The piezoelectric oscillator according to claim 5, wherein the potentiometer is a digital potentiometer having a memory, and the memory stores therein a value of a variable resistance.

14. The piezoelectric oscillator according to claim 6, wherein the potentiometer is a digital potentiometer having a memory, and the memory stores therein a value of a variable resistance.

15. The piezoelectric oscillator according to claim 7, wherein the potentiometer is a digital potentiometer having a memory, and the memory stores therein a value of a variable resistance.

16. The piezoelectric oscillator according to claim 8, wherein the potentiometer is a digital potentiometer having a memory, and the memory stores therein a value of a variable resistance.

17. The piezoelectric oscillator according to claim 9, wherein the potentiometer is a digital potentiometer having a memory, and the memory stores therein a value of a variable resistance.

18. The piezoelectric oscillator according to claim 10, wherein the potentiometer is a digital potentiometer having a memory, and the memory stores therein a value of a variable resistance.

19. The piezoelectric oscillator according to claim 11, wherein the potentiometer is a digital potentiometer having a memory, and the memory stores therein a value of a variable resistance.

20. The piezoelectric oscillator according to claim 12, wherein the potentiometer is a digital potentiometer having a memory, and the memory stores therein a value of a variable resistance.
